(19) United States
(12) Patent Application Publication
(10) Pub. No.: US 2016/0190365 A1
(43) Pub. Date: Jun. 30, 2016

(54) PHOTOVOLTAIC SOLAR MODULE METALLIZATION AND SHADE MANAGEMENT CONNECTION AND FABRICATION METHODS

(71) Applicant: Solexel, Inc., Milpitas, CA (US)

(72) Inventor: Mehrdad M. Moslehi, Los Altos, CA (US)

(21) Appl. No.: 14/829,635

(22) Filed: Aug. 18, 2015

Related U.S. Application Data
(60) Provisional application No. 62/038,787, filed on Aug. 18, 2014.

(51) Int. Cl. H01L 31/0224; H01L 31/0443

(52) U.S. Cl. CPC H01L 31/022458; H01L 31/0443

(57) ABSTRACT

Solar cell structures having improved efficiency, distributed shade management, and reduced fabrication complexity.

### CROSS-REFERENCE TO RELATED APPLICATIONS

This application claims the benefit of U.S. provisional patent application 62/038,787 filed on Aug. 18, 2014, which is hereby incorporated by reference in its entirety.

### BACKGROUND

Photovoltaic solar cell metallization structures and fabrication methods are constrained by necessary electrical conductivity requirements for extraction and delivery of the photovoltaic power generated by the solar cell. At the solar cell to solar cell and module level interconnections, these constraints are often increased due to the electrical connection of and an increased number solar cells. Distributed shade management solutions, including corresponding distributed shade management components such as bypass switches as well as electrical terminal connections, are often also subject to additional metallization electrical conductivity requirements at the module, solar cell to solar cell connection, and individual solar cell array level. Relatively high solar cell current often requires thicker solar cell metallization (for higher electrical conductance) as well as larger package (and more expensive) shade management components which may place increased mechanical and thermal stresses on sensitive semiconductor absorber materials such as crystalline silicon. Typical shade management solutions include module level shade management solutions housed junction boxes external to the module structure.

### BRIEF SUMMARY OF THE INVENTION

Therefore, a need has arisen for a solar cell structure having improved efficiency, distributed shade management, and reduced fabrication complexity. In accordance with the disclosed subject matter, solar cell structures are provided which may substantially eliminate or reduce disadvantages and deficiencies associated with previously developed solar cell structures.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIG. 1A is a diagram showing a top view (or sunnyside view) of a thirty cell (e.g., 5×6 arrangement) module having ten distributed cell shade management blocks;

FIG. 1B is an expanded view of FIG. 1A along the diagram x-axis of symmetry;

FIG. 2 is a diagram showing a top view (or sunnyside view) of a thirty cell (e.g., 5×6 arrangement) module having ten cell shade management blocks;

FIG. 3A is a diagram showing a backside view of the thirty cell (e.g., 5×6 arrangement) module of FIG. 1A after second level metal M2 metallization;

FIG. 3B is an expanded view of FIG. 3A along the diagram x-axis of symmetry;

FIG. 4A is a diagram showing a backside view of the thirty cell (e.g., 5×6 arrangement) module of FIG. 3A after bussing tabs (or bussing ribbons) and distributed shade management parts attachment;

FIG. 4B is an expanded view of FIG. 4A along the diagram x-axis of symmetry;

FIG. 5 is a diagram showing functionally the backside current flow from cell to cell of the thirty cell module (e.g., 5×6 arrangement) of FIG. 4A;

FIG. 6 is a schematic cross-sectional diagram of an exemplary back contact back junction solar cell; and

FIG. 7 is a representative schematic plan view (frontside or sunnyside view) diagram of a monolithic isled solar cell or icell;

FIGS. 8A and 8B are representative schematic cross-sectional view diagrams of a backplane-attached solar cell;

FIG. 9 is a high level monolithic isled solar cell and fabrication process flow; and

FIG. 10 is a high level monolithic isled solar cell and module fabrication process flow.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like aspects and identifiers being used to refer to like and corresponding parts of the various drawings.

And although the present disclosure is described with reference to specific embodiments and components, one skilled in the art could apply the principles discussed herein to other solar cell structures and materials (e.g., mono crystalline silicon or multi-crystalline silicon), fabrication processes (e.g., various deposition methods and materials such as metallization materials including but not limited to aluminum and/or copper), as well as alternative technical areas and/or embodiments without undue experimentation.

Photovoltaic solar cell structures and fabrication methods providing electrical power extraction/interconnections and distributed shade management solutions are described. These comprehensive solar cell solutions may be characterized by integrated solar cell metallization and embedded solar cell power electronics in the solar module laminate. Solar cell structures and fabrication methods may also scale cell current and voltage as desired (e.g., scaling down the solar cell current and scaling up the solar cell voltage by a positive integer equal to or greater than 2). Solar cell current and voltage scaling, in the case of decreasing (scaling down) cell current, advantageously may relax solar cell metallization conductivity (and metal thickness) requirements. Monolithic solar cell module fabrication—the processing and completion of multiple solar cells on a continuous backplane sheet at once—may provide decreased fabrication complexity resulting in substantially improved processing throughput, improved product reliability, and reduced solar cell and module manufacturing costs.

In a photovoltaic solar module, a shade management building block may be defined as the building block unit comprising more than a single solar cell within its structure for distributed power electronics implementation. For example, a shade management block may comprise multiple solar cells (e.g., 2, 3, 4 . . . ) within a building block. The number of solar cells within a shade management building block may be either an integer or a non-integer (e.g., 1.5, 2, 2.5, 3, etc.). The optimal structure and size of the shade management building block may be chosen based on a wide range of important considerations, including: voltage scaling factor, current scaling factor, shade management block power, cost and performance targets for power electronics, distributed shade management and power harvest granularity, sizing and utilization of string inverter, solar cell and module metallization requirements, placement of power electronic parts, product reliability, fault tolerance, etc.

Each shade management building block has at least two opposite polarity terminals, for example a positive emitter terminal and a negative base terminal, to which a patterned metal and/or a bussing ribbon may be attached for shade management in the case of a shade management block solar cell failure. A bypass switch, such as a Super Barrier Rectifier (SBR) or a Schottky Barrier Rectifier (SBR), acts as a switch to bypass the shade management block in the case of reduced solar cell power production or current mismatch with the rest of the series-connected string of solar cells, for example due to low light irradiation (such as due to localized shading) or solar cell failure, from a solar cell in the shade management building block. An MPPT power optimizer may provide maximum power point tracking for each shade management building block. Thus, each shade management block may have one shade management SBR and one MPPT power optimizer chip. For example: MPPT power optimizer chips and shade management SBRs may be connected to a bussing ribbon connected to a positive emitter terminal and a negative base terminal of a shade management block; the MPPT power optimizer chips and shade management SBRs are attached to the module backplane at peripheral margins of the module; shade management SBRs may be connected as output-stage SBRs at the outputs of a MPPT power optimizer chips.

Key solar cell and module metallization structure and material considerations include electrical conductivity (or electrical resistivity) and metal-related ohmic losses, for example due to current flow and I²R losses. Additionally, shade management power electronics, such as bypass switches, operate under current constraints which typically increase in complexity and//or cost (and package size and thermal dissipation losses) corresponding to an increase in solar cell current.

To reduce solar cell current, and thus relax metallization requirements (such as reduce metal thickness) and size cost of shade management components, without reducing solar cell power production, trench-partitioned isled solar cells are provided. Additionally, solar cell structure having an integrated backplane supported dual level metallization structure (e.g., comprising a first metal layer/level M1 and a second metal layer/level M2 contacting M1 through an electrically insulating backplane) providing placement of a shade management block patterned metallization or bussing conductor which is mechanically and structurally decoupled from sensitive solar cell absorber materials (e.g., silicon) is provided. Structures and methods for forming isled solar cells having integrated backplane supported dual level metallization structure referred to as an iCell may be found in related U.S. Patent Pub. 2014/0370650 published Dec. 18, 2014, which is hereby incorporated by reference in its entirety.

Monolithic module fabrication methods providing reduced processing complexity may provide advantageous solutions for fabrication and embedding shade management block bussing ribbons within a solar cell module structure. Monolithic module fabrication solutions include attaching solar cells to a backplane and forming a second level metal M2 electrically connecting the backplane attached solar cells. Structures and methods for forming monolithic solar cell modules, such as attaching solar cells to a backplane and forming a second level metal M2 electrically connecting the backplane attached solar cells, may be found in U.S. Pat. Pub. 2015/0155398 published June 4, 2015, which is hereby incorporated by reference in its entirety. Structures and methods for forming monolithic solar cell modules of isled solar cells having integrated backplane supported dual level metallization structure may be found in related U.S. Patent Pub. 2014/0370650 published Dec. 18, 2014 introduced above.

A monolithic isled solar cell is a solar cell, and solar cell unit building block, made from a continuous semiconductor substrate. Thus, a monolithic isled solar cell may have a dimensions of approximately 156×156 mm (i.e., the monolithic isled solar cell is made from a 156×156 mm semiconductor substrate) or other desired dimensions, and comprise, for example, four semiconductor isles. The monolithic isled solar cell may comprise any integer number of isles (e.g., 2 to 24 isles) having a number of various isle shapes (for instance, polygonal such as rectangular isles).

Monolithic isled solar cell structures decrease the current and increase the voltage compared to a non-isled solar cell by a factor (N) of the number of semiconductor isles (or groups of isles) connected in electrical series. The monolithic isled solar cell may be considered a building block unit for power electronics (such as including shade management diodes and/or MPPT power optimizers), the product of current and voltage scaling factors is always one (e.g., current reduced by a factor of 1/N and voltage increased by a factor of N). Thus, the monolithic isled solar cell example above of a 156×156 mm monolithic isled solar cell having four series-connected semiconductor isles (N=4) will have 1/4× current and 4× voltage scaling as a non-isled 156×156 mm (*or any other size) similar structure solar cell—in other words current scaled down or reduced by a factor of four and voltage scaled up or increased by a factor of four. In one particular instance, a sixty cell (e.g., 10×6 cell) module of monolithic isled solar cells each having two series-connected semiconductor isles may have solar module voltage characteristics of Voc (max at −40° C./1 SUN) of approximately 99.80 V and V_{MP} (at standard test conditions STC) of approximately 85.80 V and module current of Isc (max at 85° C./1 SUN) of approximately 4.98 A and I_{MP} (at standard test conditions STC) of approximately 4.82 A—thus substantially relaxing metallization conductivity requirements and corresponding mechanical and thermal induced stresses on the silicon absorber via reduced metallization thickness and shade management component package size.

A shade management block may be defined as a building block unit comprising from a fraction (multiple of <1) to one single monolithic isled solar cell to more than a single (multiple of >1) monolithic isled solar cell within its structure for distributed power electronics implementation in a monolithic module. For example, a shade management block may comprise a fraction F (up to 100%) of M single monolithic isled solar cells, wherein M may be either an integer or a fractional number (e.g., M=3/2, 2, 5/2, 3, etc.)

The optimal structure and size of a shade management block of monolithic isles solar cells in a monolithic module may be chosen based on a wide range of important considerations, including: voltage scaling factor, current scaling factor, shade management block power, cost and performance targets for power electronics, distributed power harvest granularity, sizing and utilization of string inverter, monolithic module metallization requirements, placement of electronic parts, number of pattern of monolithic isled solar cell scribe lines forming semiconductor isles, reliability, fault tolerance, etc.

Metallization considerations, such as those noted above, may be particularly important constraints in solar cell and module structures. For example, the second level metal (M2) constraints in a dual level metallization structure for monolithic isled solar cells, such as that described in U.S. Patent Pub. 2014/0370650 published Dec. 18, 2014, in a module having sixty cells may vary across monolithic isled solar cells having one to six number of semiconductor isles (i.e., N=1 to 6) and shade management building blocks of three monolithically isled solar cells as shown in Table 1.

Table 1 shows the required M2 metal (e.g., PVD metal and/or plated metal and/or metal foil) thickness vs N (1 to 6) for either aluminum or copper M2 metallization and various loss factors. The following assumptions are used in the calculations of Table 1: ρ=1.68 μΩ.cm for copper; ρ=2.82 μΩ.cm for aluminum; Pₘₚ=5.5 W; Iₘₚ=9.3 A; allowable power loss factors of k=0.01, 0.005, or 0.0025 (the loss factor does not include effects of any current choking, for example current choking from M2 90-degree bends or U turns). Note: k=0.0025, or 0.25% relative, corresponds to M2 metallization loss allowance of approximately 0.25% relative and 0.05% absolute cell efficiency loss. The bottom numbers (underlined) below the top numbers (italicized) show the required metal thickness if the metal resistivity is 30% higher than the bulk value (i.e., 3.67 μΩ.cm instead of 2.82 μΩ.cm for aluminum, and 2.18 μΩ.cm instead of 1.68 μΩ.cm for copper).

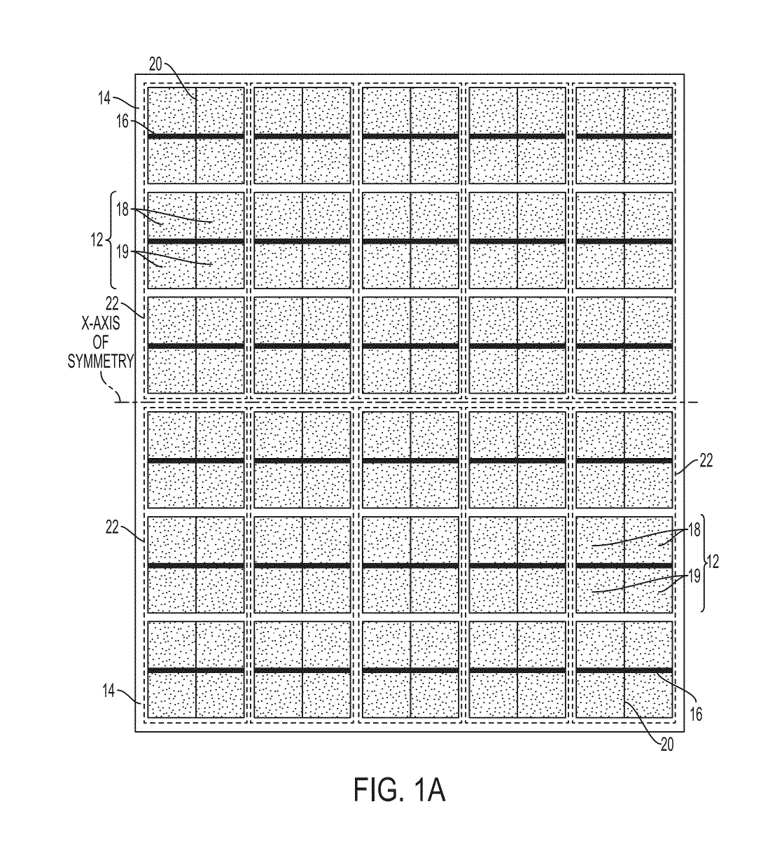

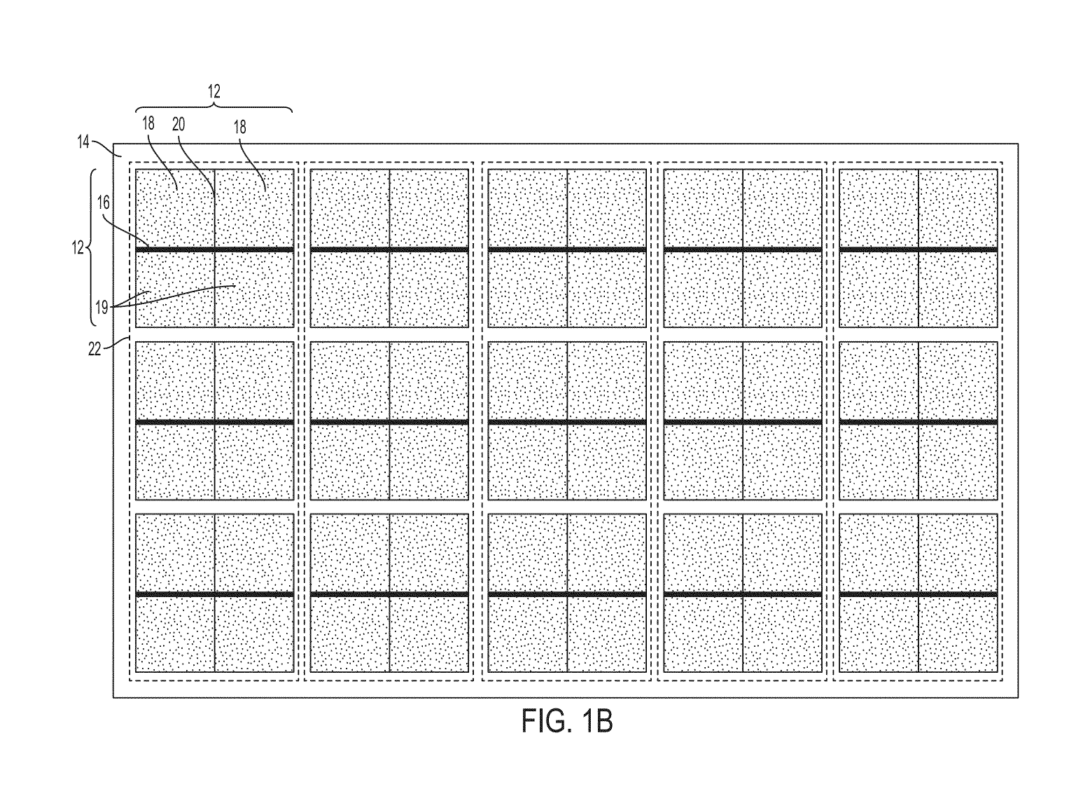

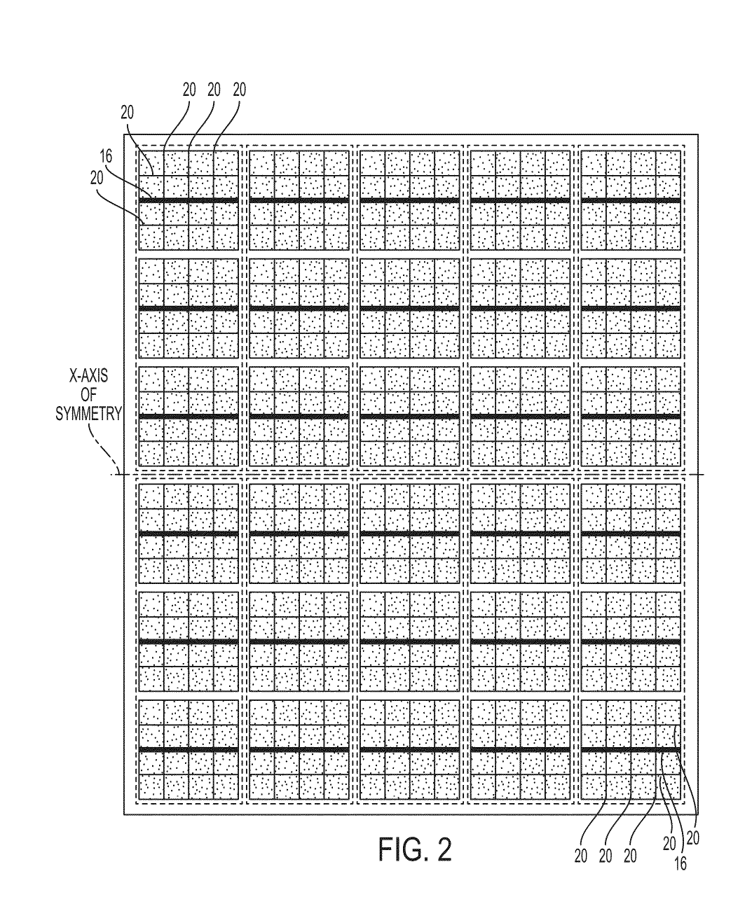

For example, in a sixty monolithic isled solar cell module where N=2 (i.e., two semiconductor isles connected in series per monolithic isled solar cell) for each monolithic isled solar cell (e.g., formed by one electrical scribe line and one mechanical scribe line as shown in FIG. 1A, or formed by one electrical scribe line and five mechanical scribe lines as shown in FIG. 2) monolithic isled solar cell module voltage is scaled up by a factor of two (2×) and current is scaled down by a factor of two (1/2×) to achieve a loss factor (K) of 0.0025 (K=0.0025) may require a second level metallization M2 thickness of approximately 15 μm of copper (e.g., Cu foil or plated Cu such as, for example, a combination electroplated and electroless Cu of 0.25 μm nickel+0.25 μm electroless copper+15 μm electroplated Cu) or approximately 25 μm of aluminum (e.g., Al foil), as gleaned from Table 1. In fabrication, this M2 metallization may be a metal foil (e.g., Cu or Al) or plated copper M2 metallization.

In another example, in a sixty monolithic isled solar cell module where N=4 (i.e., four semiconductor isles connected in series per monolithic isled solar cell) for each monolithic isled solar cell (e.g., formed by three electrical scribe lines and three mechanical scribe lines) monolithic isled solar cell module voltage is scaled up by a factor of four (4×) and current is scaled down by a factor of four (1/4×) to achieve a loss factor (K) of 0.0025 (K=0.0025) may require a second level metallization M2 thickness of approximately 4 μm of copper or approximately 6 μm of aluminum, as gleaned from Table 1. In fabrication, this may be an aluminum evaporation, laminated metal foil (Cu or Al), or thin plated copper M2 metallization.

TABLE 1
Required M2 metal (e.g., metal foil) thickness vs N (1 to 6) for either
aluminum or copper M2 metallization and various loss factors.

| | t (μm) for | t (μm) for | t (μm) for | t (μm) for | t (μm) for | t (μm) for |
|---|---|---|---|---|---|---|
| N | k = 0.01, Cu | k = 0.005, Cu | k = 0.0025, Cu | k = 0.01, Al | k = 0.005, Al | k = 0.0025, Al |
| 1 | 13.21 | 26.42 | 52.84 | 22.17 | 44.35 | 88.69 |
| | 17.17 | 34.35 | 68.69 | 28.82 | 57.66 | 115.30 |
| 2 | 3.30 | 6.60 | 13.21 | 5.54 | 11.09 | 22.17 |
| | 4.29 | 8.58 | 17.17 | 7.20 | 14.42 | 28.82 |
| 3 | 1.47 | 2.94 | 5.87 | 2.46 | 4.93 | 9.85 |
| | 1.91 | 3.82 | 7.63 | 3.20 | 6.41 | 12.81 |
| 4 | 0.83 | 1.65 | 3.30 | 1.39 | 2.77 | 5.54 |
| | 1.08 | 2.15 | 4.29 | 1.81 | 3.60 | 7.20 |
| 5 | 0.53 | 1.06 | 2.11 | 0.89 | 1.77 | 3.55 |
| | 0.69 | 1.38 | 2.74 | 1.16 | 2.30 | 4.62 |
| 6 | 0.37 | 0.73 | 1.47 | 0.62 | 1.23 | 2.46 |
| | 0.48 | 0.95 | 1.91 | 0.81 | 1.60 | 3.20 |

FIG. 1A is a diagram showing a top view (or sunnyside view) of a thirty cell (5×6) module having ten cell shade management building blocks each comprising three monolithic isled solar cells. Thirty cell module has thirty monolithic isled solar cells 12 (e.g., thirty 156×156 mm solar cells) in a representative five by six module array (other array configurations are also possible) on backplane 14. Each monolithic isled solar cell 12 has two (N=2) series-connected semiconductor isle 18 and semiconductor isle 19 defined by monolithic trench isolation scribe 16 (shown as a horizontal monolithic trench isolation scribe). Each monolithic isled solar cell 12 also may have optional mechanical scribe line 20 (shown as a vertical mechanical scribe line parallel to the direction of the current flow) for improved micro-crack mitigation and solar cell bendability; however, semiconductor isles do not refer to regions formed along mechanical scribe lines as second level metal M2 on the backside of the solar cell essentially ignores mechanical scribe lines. In other words, semiconductor isles (and corresponding current and voltage scaling) in monolithic isled solar cell are defined by monolithic trench isolation scribes which define the series-connected isles. Thus, monolithic isled solar cells 12 of FIG. 1 each have two semiconductor isles 18 and 19 and N=2. Each shade management building block 22 is formed of three columnar monolithic isled solar cells 12. Thus, there are ten shade management blocks 22 in the thirty cell module. Each shade management block 22 comprising three monolithic isled solar cells 12 (e.g., each monolithic isled solar cell having a size of 156×156 mm) has a voltage increase scaling factor of six (6×) and a current decrease scaling factor of two (1/2×). The product of the current and voltage scaling factors for this representative shade management building block is ½×6=3 which is the number of monolithic isled solar cells within the shade management building block. FIG. 1B is an expanded view of FIG. 1A along the diagram x-axis of symmetry.

Alternatively, in an N=4 monolithic isled solar cell embodiment (e.g., each monolithic isled solar cell comprising three horizontal electrical isolation scribes forming four semiconductor isles), each shade management block comprising three monolithic isled solar cells has a voltage increase scaling factor of twelve (12) and a current decrease scaling factor of four (1/4).

FIG. 2 is a diagram showing a top view (or sunnyside view) of a thirty cell module having ten cell shade management blocks each comprising three monolithic isled solar cells consistent with the module of FIG. 1A except that each monolithic isled solar cell has additional mechanical scribe lines 20 shown as an additional two vertical mechanical scribe lines and an additional two horizontal scribe lines.

In an alternative embodiment, the horizontal mechanical scribe lines shown in FIG. 2 may be electrical scribe lines thus forming four semiconductor isles (each semiconductor isle having corresponding second level metal M2 base and emitter metallization including second level emitter finger and busbar metallization and second level base finger and busbar metallization) resulting in a N=4 monolithic isled solar cell.

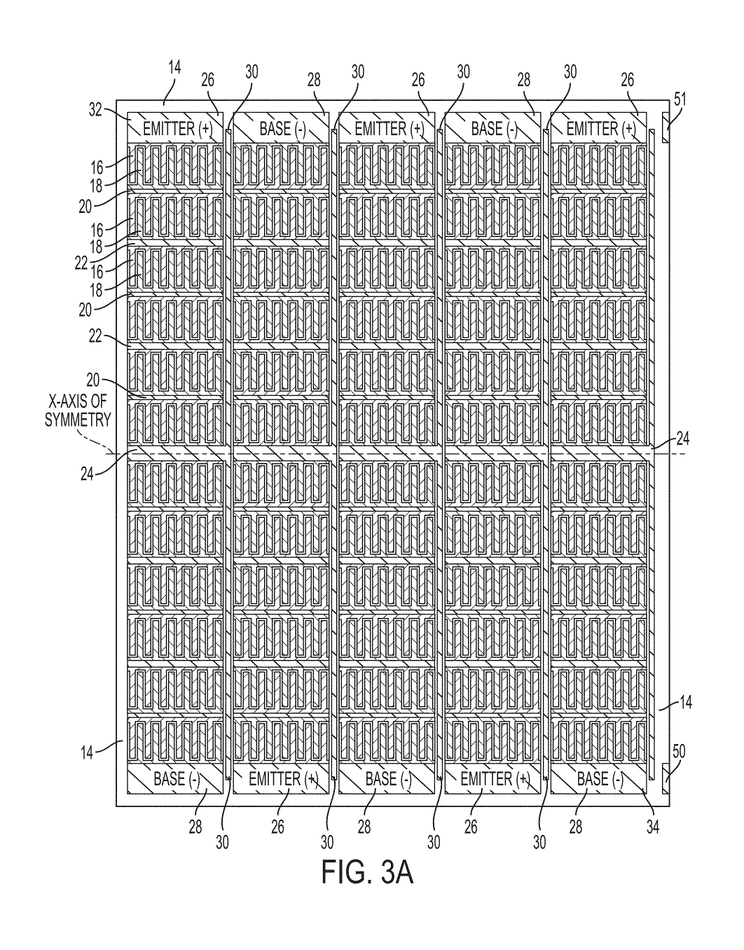

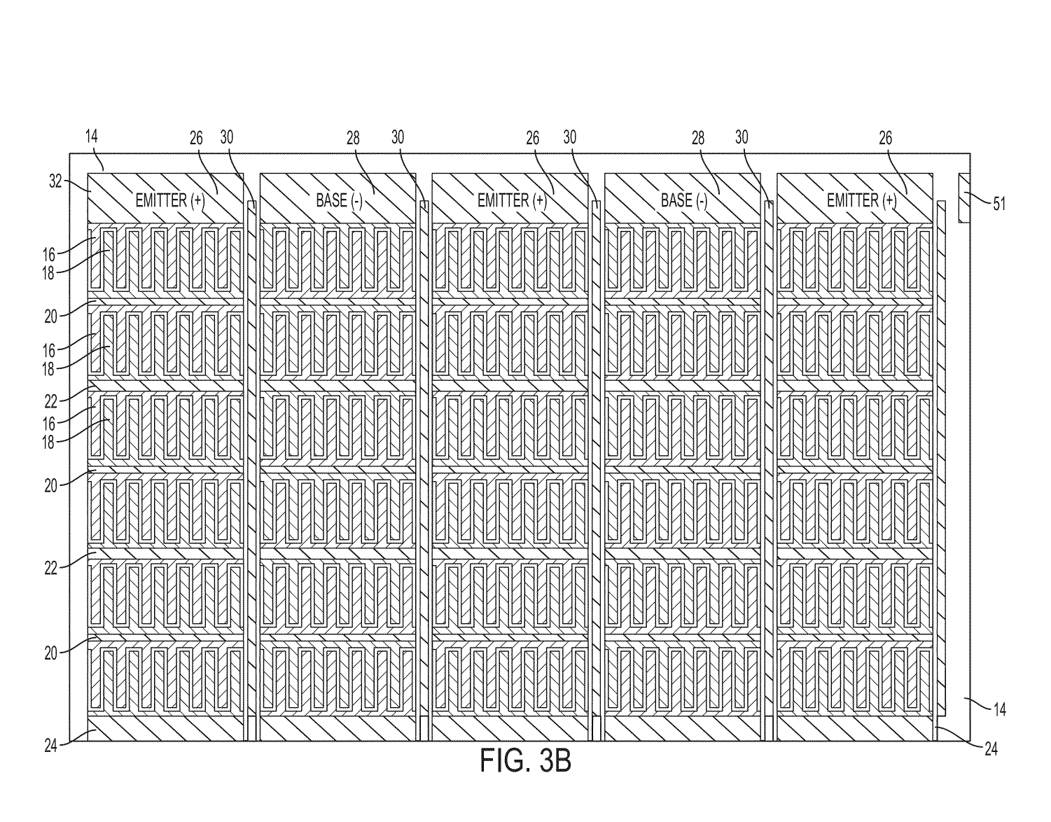

FIG. 3A is a diagram showing a backside view of the thirty cell module of FIG. 1A after second level metal M2 metallization and before bussing ribbon and shade management parts placement. Second level metal M2 metallization may contact solar cell backside first level M1 metallization through backplane vias as described in U.S. Patent Pub. 2014/0370650 published Dec. 18, 2014. In some instances, metal paste landing pads (e.g., aluminum or copper) on the first level M1 metallization (e.g., aluminum or copper) having an element to braze (metal joining) or solder the second level metal (e.g., aluminum or copper) to the landing pads may be advantageous for forming reliable M2 to M1 connection in the vias (e.g., laser drilled vias) through an electrically insulating backplane (e.g., a prepreg sheet)—for example, Al paste landing pads having an added element on first level M1 metallization. Screen-printed Al paste for first level metal M1 metallization landing pads may serve two key purposes: end-pointing landing pads during laser drilling of via holes through backplane (to prevent punching through and causing electrical shunts); and, electrical interconnections between the patterned M2 and M1 layers. A dual-screen-print M1 process enables the use of two different Al-containing paste materials for the main first level metal M1 metallization contact metallization and the first level metal M1 metallization landing pads. Dual-screen-print first level metal M1 metallization structure (main M1 contact metallization and landing pads) may be co-sintered in the same process step at approximately 550° C. to 570° C. The M1 landing pad paste may comprise mainly aluminum but with a suitable additive element which facilitates brazing or soldering of the M2 metal (Al or Cu) to the M1 metal through conductive via plugs (fused/soldered landing pads to M2). If using an additive in the paste, the additive to the landing pad Al paste should meet key requirements, including but not limited to: enable soldering or thermal brazing of M2 foil (Al or Cu) to the landing pad under vacuum lamination press at temperatures of approximately 250° C. to 300° C., either directly under lamination, or by adding a solder material in the vias, or by laser-assisted welding; and, aluminum-additive blended material should be compatible with a co-sintering process temperature of approximately 550° C. to 570° C. (to enable single sinter process and tool use).

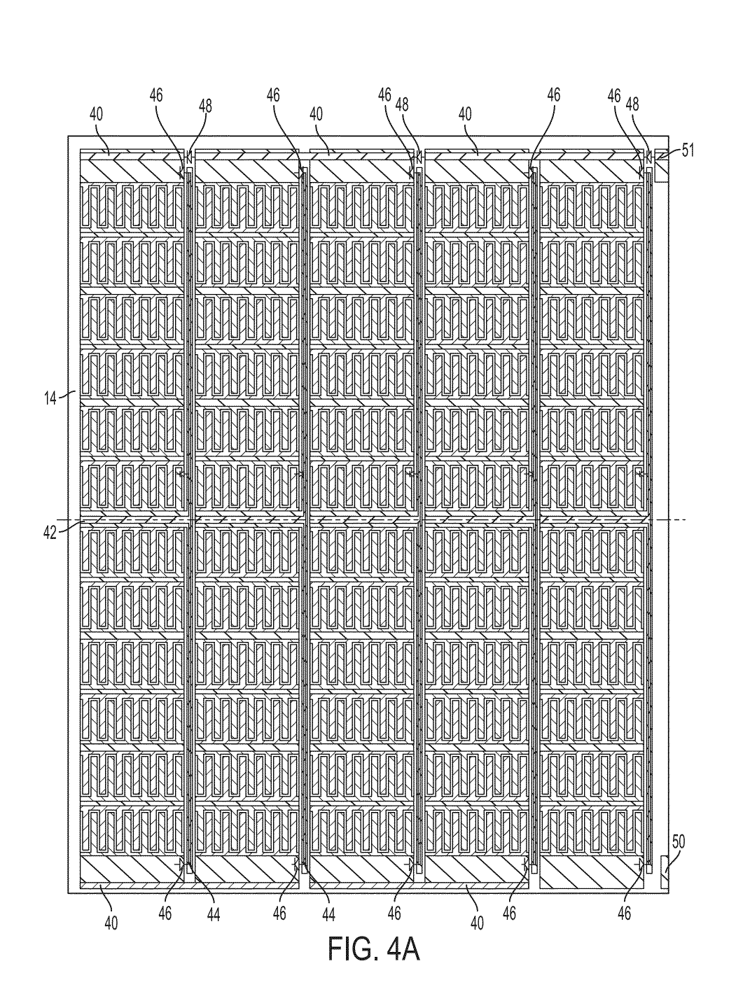

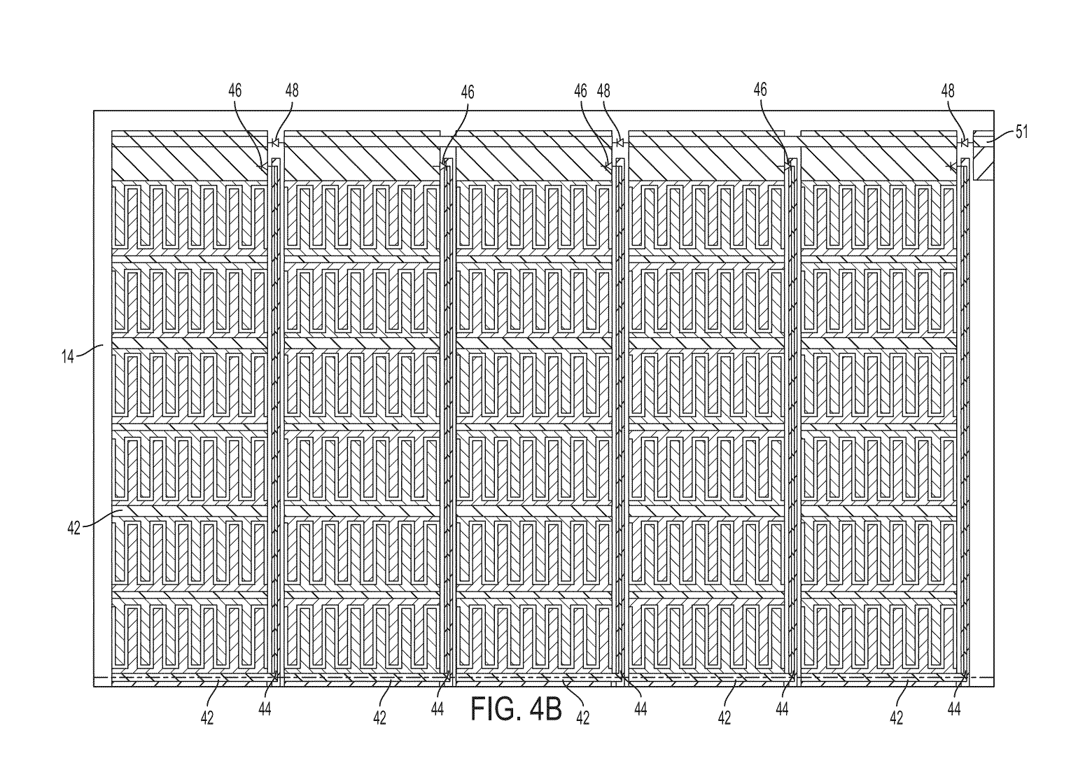

Second level metallization M2 is formed on the backside backplane 14 and contacts first level metallization M1 of each monolithic isled solar cell through backplane 14 (e.g., using via holes). Second level emitter finger and busbar metallization 16 collects positive current and contacts solar cell emitter metallization on the backside of monolithic isled solar cells 12 through backplane 14. Second level base finger and busbar metallization 18 collects negative current and contacts solar cell base metallization on the backside of monolithic isled solar cells 12 through backplane 14. Second level metal semiconductor isle connectors 20 connect the two semiconductor isles 18 making up each monolithically isled solar cell 12 as base-to-emitter and emitter-to-base connections. Second level metal monolithic isled solar cell connectors 21 connect each monolithically isled solar cell 12 in each shade management block 22 as base-to-emitter and emitter-to-base connections. Second level metal M2 connectors 24 connect shade management building blocks 22 as base-to-emitter and emitter-to-base connections—in other words as shown in FIG. 3A, second level metal M2 connectors 24 connect shade management blocks 22 in columns. Second level metal M2 connectors 24 also are connected to columnar metal fingers 30. Columnar emitter extensions 26 and columnar base extensions 28 are formed at the top and bottom of each solar cell column (module columnar connection tabs 40 and shade management bypass switch 48 attached to columnar emitter extensions 26 and columnar base extensions 28 as shown in FIG. 4A). Module positive polarity output terminal 32 and module negative polarity output terminal 34 provide module level power connection. Module stitching terminals 50 and 51 are positioned on the module periphery. FIG. 3B is an expanded view of FIG. 3A along the diagram x-axis of symmetry.

FIG. 4A is a diagram showing a backside view of the thirty cell (e.g., 5×6) monolithic module of FIG. 3A after bussing tabs (or bussing ribbons) and shade management parts placement/attachment. Bussing tabs and shade management parts may be attached (e.g., soldered or welded) to second level M2 metallization (e.g., using surface mount technology component placement systems). Module columnar connection tabs 40 are attached to columnar emitter extensions 26 and columnar base extensions 28. Interconnecting tabs 42 are connected to second level metal M2 connectors 24 for series connected columnar shade management blocks. Shade management ribbon tabs 44 are connected to the base polarity and emitter polarity of each shade management block. Each shade management ribbon tab 44 is associated with a shade management bypass switch 46 (e.g., a Super Barrier Rectifier or Schottky Barrier Rectifier: SBR). Shade management bypass switches 48 (e.g., a Super Barrier Rectifier or Schottky Barrier Rectifier: SBR) are connected to groups of groups of four series connected shade management building blocks 22 (or in other words shade management bypass switches 48 connect to two adjacent columns of monolithic isled solar cells totaling twelve cells or six per column) via columnar emitter extensions 26 and columnar base extensions 28 and module columnar connection tabs 40 for increased fault tolerance and reliability. Module negative stitching terminal 50 provides a connection pad for additional module connection. FIG. 4B is an expanded view of FIG. 4A along the diagram x-axis of symmetry. Shade management bypass switches 48 may also comprise an MPPT power optimizer component. For example, the shade management SBR may be connected as an output-stage SBR at the output of the MPPT power optimizer chip attached to shade management ribbon tab 44.

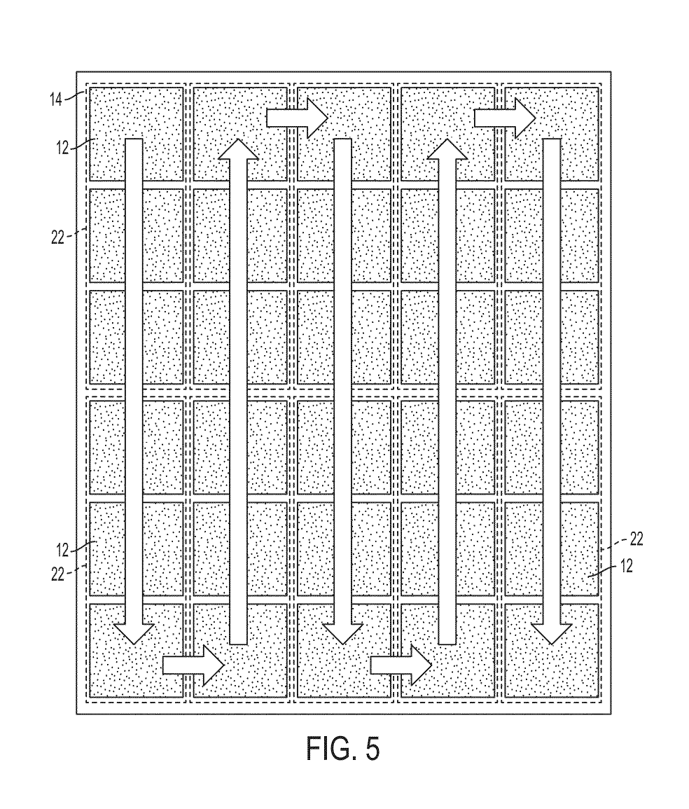

FIG. 5 is a diagram showing functionally the backside current flow from cell to cell of the thirty cell (5×6) monolithic module of FIG. 4A. Current is transferred by a second level M2 metallization and tabs on the backside of the solar cells and monolithic module as shown in FIG. 4A. The current flow provided by structures shown in FIGS. 1A, 3A, and 4A provide columnar current flow thus substantially mitigating intra-cell ohmic losses due to current bending and turning. In other words, there are no second level M2 metallization 90° bends or U-turns. For example, current only turns at the module periphery via module columnar connection tabs 40 connected to columnar emitter extensions 26 and columnar base extensions 28. Current flows vertically to minimize ohmic losses and 90° current turns at the module periphery are assisted by module columnar connection tabs 40. Second level M2 metallization provides base and emitter metallization and semiconductor isles to isle and solar cell to solar cell connection as well as landing pads bussing tabs and shade management parts placement.

Tabs (e.g., bussing ribbon interconnects) described in FIG. 4A may be categorized into two types based on conductivity requirements. Type 1 tabs include module columnar connection tabs 40 and connect adjacent shade management blocks columns of solar cells in electrical series and may also connect additional fault tolerant Super Barrier Rectifiers to four shade management building blocks (or in other words two columns of solar cells). Type 1 tabs are placed at the peripheral edges of the monolithic module. Type 1 tabs should have very low dissipation losses since they carry the module current at all times (with or without shading of any cells within the module). For example, Type 1 tabs may be relatively wide and/or thick copper ribbons with length of approximately two monolithic isled solar cells (e.g., 5 mm wide, 0.6 mm thick, and approximately 312 mm long resulting in power dissipation of 0.0427 W (i.e., [(0.01368 W/cm)/(2×5)]×31.2 cm) and approximately 0.26% relative power loss per shade management block (i.e., 0.0427 W/16.62 W). Thus, Type 1 tabs may be 5 mm wide/0.6 mm thick copper ribbon (e.g., positioned at the module periphery).

Type 2 tabs include interconnecting tabs 42 and shade management ribbon tabs 44. Type 2 tabs are place between solar cell columns (columnar) and also at the mid-module boundary (mid-plane) to provide access to the opposite polarities (e.g., positive and negative busbars) of the shade management blocks for shade management protection of the shade management block via shade management bypass switches (e.g., Super Barrier Rectifiers or Schottky Barrier Rectifier: SBR), and optionally MPPT power optimizers, shown as shade management bypass switches 46 in FIG. 4A. Compared to the Type 1 tabs, the allowance for power loss in Type 2 tabs is much higher as Type 1 tabs carry the module current only when their associated shade management building blocks are subject to shading and are bypassed by their designated bypass switches (e.g., SBRs). Type 2 tabs also include the mid-plane tabs placed at the mid-plane axis of monolithic module.

The columnar and mid-plane Type 2 tabs may be relatively narrow (e.g., 1 mm wide) Cu ribbons with an approximate copper bussing ribbon length of 47 cm for columnar tabs (e.g., shade management ribbon tab 44 of FIG. 4A) and approximately 15.7 cm for mid-plane tabs (e.g., interconnecting tabs 42 of FIG. 4A). For example, assume an effective Cu ribbon resistivity of approximately 2 μΩ.cm (Cu bulk resistivity is 1.68 μΩ.cm), a Cu ribbon thickness of 0.3 mm, a Cu ribbon width of 1 mm, and a STC current value of Iₘₚ=4.53 A for shade management block of monolithic isled solar cells, the ohmic loss per unit length (cm) of such ribbon at STC condition is as follows: Pₗₒₛₛ=[2×10⁻⁶ Ω.cm/(0.1 cm×0.03 cm)]×4.53² A²=0.01368 W/cm; and, total copper ribbon tab loss along the columnar length of shade management block (when the shade management SBR is forward biased): P_{M-iCell}≈15.7 cm×3×0.01368 W/cm≈0.64 W. Note: using a Cu ribbon thickness of 0.6 mm and a Cu ribbon width of 1 mm, then: P_{V-M-iCell}≈15.7 cm×3×[2×10⁻⁶ Ω.cm/(0.1 cm×0.06 cm)]×4.53² A²≈0.32 W. For a shade management block having STC power of 16.62 W, 0.32 W corresponds to 1.93% ribbon loss which only occurs only during shade management (i.e., loss does not occur during normal operation).

Further, assuming 2 mm wide, 0.3 mm thick, and 312 mm (columnar tab such as shade management ribbon tabs 44 of FIG. 4A)+156 mm (mid-plane tab such as interconnecting tabs 42 of FIG. 4A) long Cu for Type 2 tabs, the max power dissipation may be 0.32 W (i.e., [(0.01368 W/cm)/2]×(31.2+15.6 cm) and approximately 1.93% relative power loss per shade management block (0.32 W/16.62 W). A 1.93% power dissipation may be sufficiently low for Type 2 tabs as the SBR power dissipation (when the SBR is activated for a shade management block) may be 4.53 A×0.4 V≈1.8 W (corresponding to 1.8 W/16.62 W=0.11 or 11% relative power loss). When a shade management block is bypassed by its SBR, the total power dissipation loss for the associated Type 2 tabs and SBR is 1.93%+11%≈12.9% of the shade management block standard test condition STC power. Thus, Type 2 tabs may be 2 mm wide/0.3 mm thick, or alternatively 1 mm wide/0.6mm thick, copper ribbon (e.g., positioned at the module periphery). Both the mid-plane (horizontal) and inter-columnar (vertical) copper ribbons should have a minimum ribbon width of 1 mm and a minimum ribbon thickness of 0.30 mm. The mid-plane and inter-columnar ribbons may be applied as a series of closely-spaced segmented ribbons. A thinner ribbon may be advantageous in some instances to minimize solar cell spacing impact.

Additional considerations for columnar ribbons for SBR and MPPT Power Optimizer component placement and used as shade management block negative lead extensions (i.e., ribbons between columns of monolithic isled solar cells) follow. Assuming an effective Cu ribbon resistivity of ˜2 μΩ.cm (copper bulk resistivity is 1.68 μΩ.cm), a Cu ribbon thickness of 0.3 mm, a Cu ribbon width of 6 mm, and the STC current value of Iₘₚ=2.27 A for a shade management block, the ohmic loss per unit length (cm) of such ribbon at STC condition may be calculated as follows: Pₗₒₛₛ≈[2×10⁻⁶ Ω.cm/(0.6 cm×0.03 cm)]×2.27² A²=5.725×10⁻⁴ W/cm so the total Cu ribbon loss along the columnar (vertical) length of the shade management block (for an MPPT power optimizer): P_{V-M-iCell}≈15.7 cm×3×5.725×10⁻⁴ W/cm≈0.027 W. Thus, a shade management block having STC power of 16.62 W, 0.027 W corresponds to 0.162% ribbon loss. This ribbon loss occurs during the normal operation of the module with MPPT optimizers. Assuming an effective Cu ribbon resistivity of ˜2 μΩ.cm (copper bulk resistivity is 1.68 μΩ.cm), a Cu ribbon thickness of 0.6 mm, a Cu ribbon width of 6 mm, and the STC current value of Iₘₚ=2.27 A for a shade management block, the ohmic loss per unit length (cm) of such ribbon at STC condition is as follows: Pₗₒₛₛ≈[2×10⁻⁶ Ω.cm/(0.6 cm×0.06 cm)]×2.27² A²=2.863×10⁻⁴ W/cm; so the total Cu ribbon loss along the columnar (vertical) length of a shade management block (for an MPPT power optimizer): P_{V-M-iCell}≈15.7 cm×3×2.863×10⁻⁴ W/cm 0.0135 W. Thus, a shade management block having STC power of 16.62 W, 0.0135 W corresponds to 0.08% ribbon loss. This ribbon loss occurs during the normal operation of the module with MPPT optimizers. It may be advantageous to use 6 mm wide, 0.6 mm thick ribbon to limit the inter-columnar ribbon loss to ≦0.08% (a fraction of an MPPT pass-through insertion loss of approximately 0.5%) for a negative lead extension used as a columnar ribbon for SBR and MPPT Power Optimizer component placement (i.e., ribbons between columns of monolithic isled solar cells). Alternatively, using ⅛″ (3.175 mm) wide, 0.6 mm thick ribbon, the ribbon loss will be ≦0.15%.

Additional considerations for horizontal ribbons used as shade management block negative lead extensions (i.e., ribbons placed horizontally at the module half plane shown as the x-axis of symmetry in the figures herein) follow. Assuming an effective Cu ribbon resistivity of ˜2 μΩ.cm (copper bulk resistivity is 1.68 μΩ.cm), a Cu ribbon thickness of 0.3 mm, a Cu ribbon width of 1 mm, and the STC current value of Iₘₚ=2.27 A for a shade management block, the ohmic loss of lateral ribbon across the monolithic isled solar cell width at STC condition (P_{L-M-iCell}) is as follows: P_{L-M-iCell}=[(ρ.L) /(3 WT)].Iₘₚ² (obtained based on a simple integral calculation), wherein: ρ=ribbon resistivity, L=iCell side dimension, W=ribbon thickness, T=ribbon width; and P_{L-M-iCell}≈[(2×10⁻⁶ Ω.cm×15.6 cm)/(3×0.1 cm×0.03 cm)]×2.27² A²=0.01786 W. So for a shade management block having an STC power of 16.62 W, 0.01786 W corresponds to 0.107% ribbon loss. This loss occurs during the normal operation of the module with MPPT optimizers. Assuming an effective Cu ribbon resistivity of ˜2 μΩ.cm (copper bulk resistivity is 1.68 μΩ.cm), a Cu ribbon thickness of 0.6 mm, a Cu ribbon width of 1 mm, and the STC current value of Iₘₚ=2.27 A for a shade management block, the ohmic loss per unit length (cm) of such ribbon at STC condition is as follows: P_{L-M-iCell}=[(ρ.L)/(3 WT)].Iₘₚ² (obtained based on a simple integral calculation), wherein: ρ=ribbon resistivity, L=iCell side dimension, W=ribbon thickness, T=ribbon width; and P_{L-M-iCell}≈[(2×10⁻⁶ Ω.cm×15.6 cm)/(3×0.1 cm×0.06 cm)]×2.27² A²=0.00893 W. Thus, for a shade management block having an STC power of 16.62 W, 0.00893 W corresponds to 0.05% ribbon loss. This loss occurs during the normal operation of the module with MPPT optimizers. It may be advantageous to use a 1 mm wide, 0.6 mm thick ribbon as horizontal ribbons used as shade management block negative lead extensions (i.e., ribbons placed horizontally at the module half plane shown as the x-axis of symmetry in the figures herein) to limit the lateral mid-plane ribbon loss to ≦0.05% (a fraction of the MPPT pass-through insertion loss of ˜0.5%). Alternatively using a 1-mm wide, 0.3-mm thick ribbon, the ribbon loss may be ≦0.11%.

Further, the losses per shade management block for inter-columnar and mid-plane ribbons for SBR and MPPT Power Optimizer component placement may be calculated as follows. If using 6 mm wide/0.6 mm thick inter-columnar copper ribbons and 1 mm wide/0.6 mm thick mid-plane lateral copper ribbons in the module: total ribbon loss per shade management block=P_{V-M-iCell}+P_{L-M-iCell}=0.0135+0.00893 W=0.02243 W; maximum total normalized ribbon loss per shade management block=0.02243/16.62≈0.13%. Including a MPPT Power Optimizer chip pass-through mode maximum insertion loss of 0.50%, the total insertion loss of MPPT power optimizer chip and copper ribbons may be ≦0.63% relative (or <0.14% in absolute efficiency loss) thus achieving a low total insertion loss. If using 3.175 mm wide/0.6 mm thick inter-columnar copper ribbons and 1 mm wide/0.6 mm thick mid-plane lateral copper ribbons in the module: total ribbon loss per shade management block=P_{V-M-iCell}+P_{L-M-iCell}=0.0255+0.00893 W=0.03444 W; maximum total normalized ribbon loss per shade management block=0.03444/16.62≈0.20%. Including an MPPT Power Optimizer chip pass-through mode maximum insertion loss of 0.50%, the total insertion loss of MPPT power optimizer chip and copper ribbons will be ≦0.70% relative (or ≦0.15% in absolute efficiency loss), thus achieving a low total insertion loss. It may be advantageous to use ≧3.175 mm (⅛″) wide/0.6 mm thick inter-columnar ribbons and 1 mm wide/0.6 mm thick lateral ribbons (e.g., particularly advantageous in modules having monolithic isled solar cells with four semiconductor isles N=4). This may result in total MPPT+ribbon insertion loss of ≦0.70% (0.50% for MPPT+0.20% for ribbons) or 0.15% in absolute efficiency loss

Spacing between cells, such as monolithic isled cells, should be designed for close cell to cell placement. For example, between monolithic isled cells spacing of 0.5 to 1 mm with a second level M2 metallization pattern offset from the cell edge (e.g., second level M2 metallization offset from the cell edge by approximately 1 to 2 mm). Assuming an inter-columnar ribbon placement accuracy of ±0.75 mm on the backplane, minimum ribbon-to-cell M2 separation of 1 mm, and a cell-to-cell spacing of 1 mm ±0.25 mm, advantageous M2 offset from the vertical edge of each monolithic isled solar cell in the shade management block to prevent any undesirable electrical bridging shorts may be 2 mm. Each shade management block uses one mid-plane lateral ribbon (e.g., 1 mm wide, 0.3 or 0.6 mm thick). Assuming a ribbon placement accuracy of ±0.75 mm on the backplane, minimum mid-plane ribbon-to-ribbon separation of 1 mm, and a cell-to-cell spacing of 1 mm ±0.25 mm, the minimum required width of monolithic isled solar cell busbars may be calculated as follows: busbar width=[2×(1 mm+2×0.75 mm)+1 mm−(1 mm−0.25 mm]/2+1 mm≈3.6 mm. Thus, 4 mm wide base and emitter busbars for each shade management block may be used.

Larger modules (e.g., having 60, 90, 120, or 150 cells) may be formed by stitching of a thirty cell modules together in series or parallel strings. After second level metal M2 patterning, the tabs and power electronic placements may be attached in two different patterns on two different thirty cell modules in preparation for subsequent stitching. In other words, after identical second level metal M2 formation on two modules, Type 1 tab placement and corresponding electronic component placement may be positioned differently on each module such that the modules may be stitched together in a series string (e.g., stitched together using soldered tabs such as copper tabs at the top and bottom of adjacent modules). Additional module stitching fabrication processes may include backplane laser trimming, mechanically securing the modules together (e.g., using thin adhesive tape or glue), and solder of copper tabs at designated locations on the adjacent modules. Adjacent module stitching may be performed concurrently with Type 1 and Type 2 ribbon and component placement for fabrication efficiency.

Relating to monolithically isled solar cells and the dual level metallization and backplane structures discussed herein such as those described in U.S. Patent Pub. 2014/0370650 published Dec. 18, 2014 reference above.

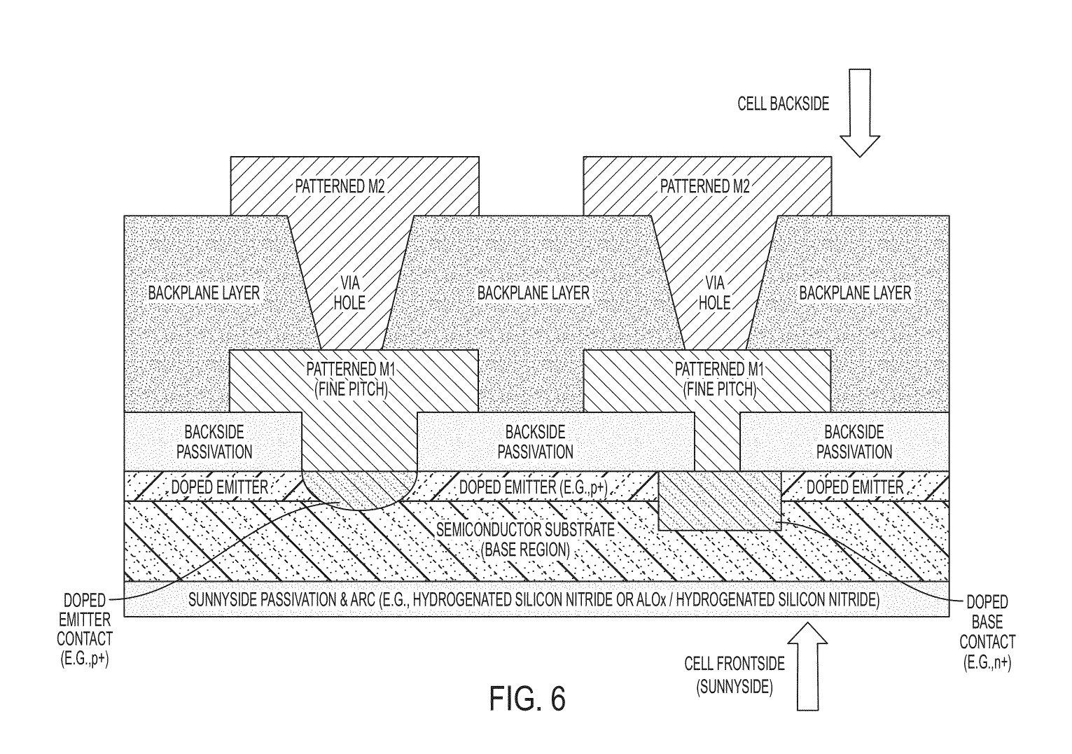

FIG. 6 is a schematic cross-sectional diagram of an exemplary back contact back junction solar cell. The back-contact solar cell of FIG. 6 utilizes a two level metallization structure Metal 1 (M1) in conjunction with an electrically insulating backplane layer, providing base and emitter metallization and Metal 2 (M2) patterned orthogonally to fine-pitched interdigitated M1 and providing cell to cell interconnection. For descriptive purposes, M2 is shown connected to both base and emitter M1 metallization; however, if M2 is patterned orthogonally to M1, M2 base metallization only contacts to M1 base metallization and M2 emitter metallization only contact M1 emitter metallization.

In some instances, the voltage may be scaled up and the current scaled down current to enable use of much smaller/less expensive components (allowing for lamination improvement and reducing component package and module thickness) and reduce dissipation losses associated with bulkier components. Locally at the cell level, reducing size of component reduces dissipation losses (in some instances resulting in a fraction of the dissipation losses). Further, reducing size of MPPT chip improves reliability and practicality and reduces cost.

A solar cell having isled sub-cells and referred to herein as a monolithically isled solar cell or iCell may be used to increase (scale-up) voltage and decrease (scale-down) current to enable low-cost, low-loss distributed power electronics.

Physically or regionally isolated isles (i.e., the initial semiconductor substrate partitioned into a plurality of substrate isles supported on a shared continuous backplane) are formed from one initially continuous semiconductor layer or substrate—thus the resulting isles (for instance, trench isolated from one another using trench isolation regions or cuts through the semiconductor substrate) are monolithic—attached to and supported by a continuous backplane (for example a flexible backplane such as an electrically insulating prepreg layer). The completed solar cell (referred to as a master cell or iCell) comprises a plurality of monolithically integrated isles/sub-cells/mini-cells, in some instances attached to a flexible backplane (e.g., one made of a prepreg materials, for example having a relatively good Coefficient of Thermal Expansion or CTE match to that of the semiconductor substrate material such as crystalline silicon), providing increased solar cell flexibility and pliability while suppressing or even eliminating micro-crack generation and crack propagation or breakage in the semiconductor substrate layer. Further, a flexible monolithically isled (or monolithically integrated group of isles) cell (also called an iCell) provides improved cell planarity and relatively small or negligible cell bow throughout solar cell processing steps such as any optional semiconductor layer thinning etch, texture etch, post-texture clean, PECVD passivation and anti-reflection coating (ARC) processes (and in some processing embodiments also allows for sunny-side-up PECVD processing of the substrates due to mitigation or elimination of thermally-induced cell warpage), and final solar cell metallization.

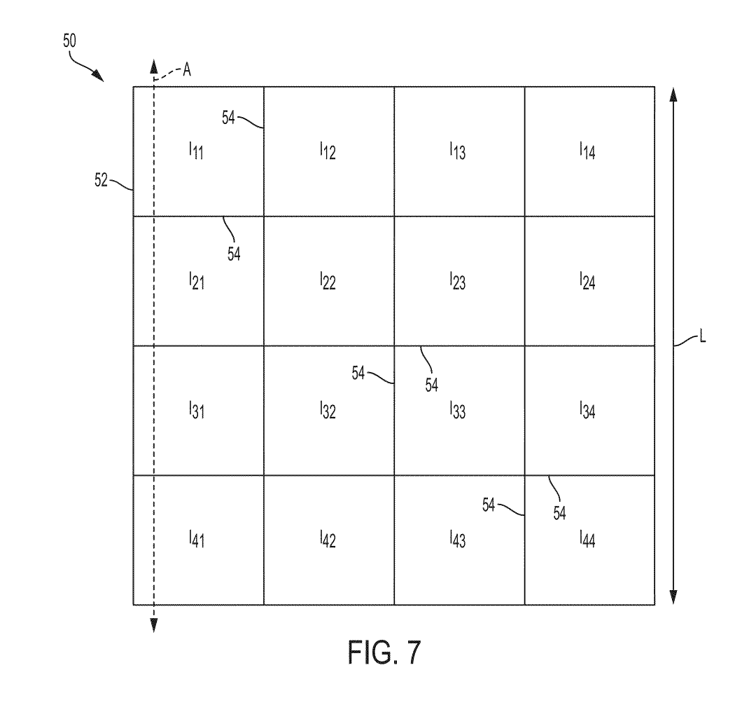

FIG. 7 is a representative schematic plan view (frontside or sunnyside view) diagram of an icell pattern (shown for square-shaped isles and square-shaped icell) along with uniform-size (equal-size) square-shaped isles for N×N=4×4=16 isles (or sub-cells, mini-cells, tiles). This schematic diagram shows a plurality of isles (shown as 4×4=16 isles) partitioned by trench isolation regions. FIG. 7 is a schematic diagram of a top or plan view of a 4×4 uniform isled (tiled) master solar cell or monolithically isled solar cell or iCell 50 defined by cell peripheral boundary or edge region 52, having a side length L, and comprising sixteen (16) uniform square-shaped isles formed from the same original continuous substrate and identified as I₁₁ through I₄₄ attached to a continuous backplane on the master cell backside (backplane and solar cell backside not shown). Each isle or sub-cell or mini-cell or tile is defined by an internal isle peripheral boundary (for example, an isolation trench cut through the master cell semiconductor substrate thickness and having a trench width substantially smaller than the isle side dimension, with the trench width no more than 100's of microns and in some instances less than or equal to approximately 100 μm—for instance, in the range of a few up to approximately 100 μm) shown as trench isolation or isle partitioning borders 54. Main cell (or iCell) peripheral boundary or edge region 52 has a total peripheral length of 4 L; however, the total iCell edge boundary length comprising the peripheral dimensions of all the isles comprises cell peripheral boundary 52 (also referred to as cell outer periphery) and trench isolation borders 54. Thus, for an iCell comprising N×N isles or mini-cells in a square-shaped isle embodiment, the total iCell edge length is N×cell outer periphery. In the representative example of FIG. 7 showing an iCell with 4×4=16 isles, N=4, so total cell edge length is 4×cell outer periphery 4 L=16 L (hence, this icell has a peripheral dimension which is 4 times larger than that of a standard square shaped cell). For a square-shaped master cell or icell with dimensions 156 mm×156 mm, square isle side dimensions are approximately 39 mm×39 mm and each isle or sub-cell has an area of 15.21 cm² per isle.

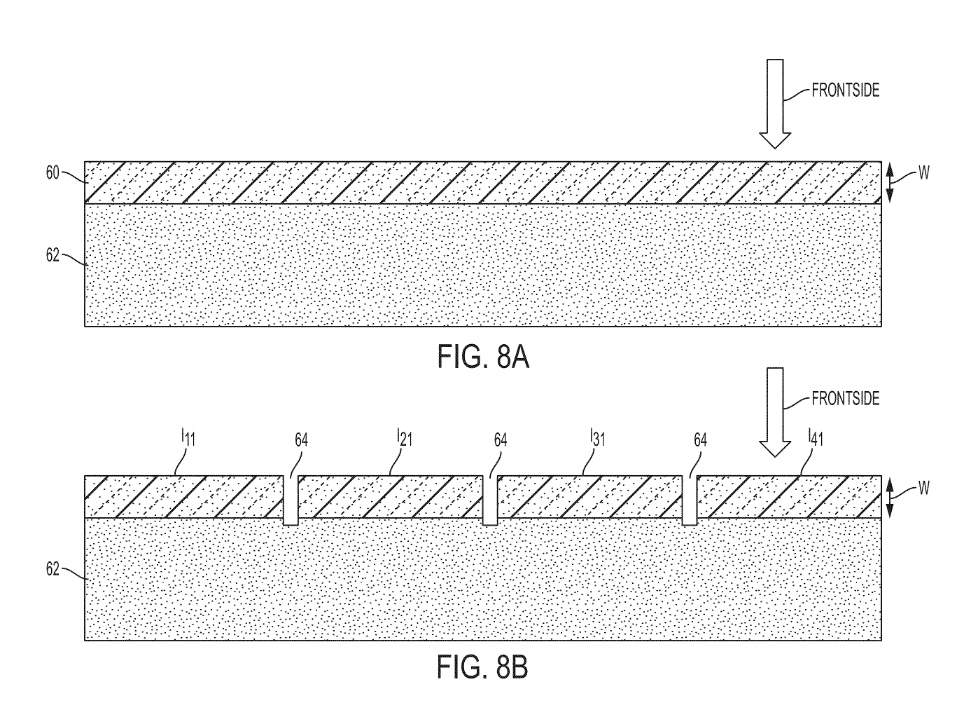

FIGS. 8A and 8B are representative schematic cross-sectional view diagrams of a backplane-attached solar cell during different stages of solar cell processing. FIG. 8A shows the simplified cross-sectional view of the backplane-attached solar cell after processing steps and before formation of the partitioning trench regions. FIG. 8B shows the simplified cross-sectional view of the backplane-attached solar cell after some processing steps and after formation of the partitioning trench regions to define the trench-partitioned isles. FIG. 8B shows the schematic cross-sectional view of the monolithic isled solar cell or iCell of FIG. 7 along the view axis A of FIG. 7 for an monolithic isles solar cell or iCell pattern (shown for square-shaped isles and square-shaped iCell), indicating the uniform-size (equal-size) square-shaped isles for N×N=4×4=16 isles (or sub-cells, mini-cells, tiles).

FIGS. 8 and 8B are schematic cross-sectional diagrams of a monolithic master cell semiconductor substrate on a backplane before formation of trench isolation or partitioning regions, and a monolithic isled or tiled solar cell on a backplane formed from a master cell after formation of trench isolation or partitioning regions, respectively. FIG. 8A comprises semiconductor substrate 60 having width (semiconductor layer thickness) W and attached to backplane 62 (e.g., an electrically insulating continuous backplane layer, for instance, a thin flexible sheet of prepreg). FIG. 8B is a cross-sectional diagram of an isled solar cell (iCell)—shown as a cross-sectional diagram along the A axis of the cell of FIG. 7. Shown, FIG. 8B comprises isles or mini-cells I₁₁, I₂₁, I₃₁, and I₄₁ each having a trench-partitioned semiconductor layer width (thickness) W and attached to backplane 62. The semiconductor substrate regions of the mini-cells are physically and electrically isolated by an internal peripheral partitioning boundary, trench partitioning borders 64. The semiconductor regions of isles or mini-cells I₁₁, I₂₁, I₃₁, and I₄₁ are monolithically formed from the same continuous semiconductor substrate shown in FIG. 8A. The monolithic isled solar cell or icell of FIG. 8B may be formed from the semiconductor/backplane structure of FIG. 8A by forming internal peripheral partitioning boundaries in the desired mini-cell shapes (e.g., square shaped mini-cells or isles) by trenching through the semiconductor layer to the attached backplane (with the trench-partitioned isles or mini-cells being supported by the continuous backplane). Trench partitioning of the semiconductor substrate to form the isles does not partition the continuous backplane sheet, hence the resulting isles remain supported by and attached to the continuous backplane layer or sheet. Trench partitioning formation process through the initially continuous semiconductor substrate thickness may be performed by, for example, pulsed laser ablation or dicing, mechanical saw dicing, ultrasonic dicing, plasma dicing, water jet dicing, or another suitable process (dicing, cutting, scribing, and trenching may be used interchangeably to refer to the process of trench isolation process to form the plurality of isles or mini-cells or tiles on the continuous backplane). Again, the backplane structure may comprise a combination of a backplane support sheet in conjunction with a patterned metallization structure, with the backplane support sheet providing mechanical support to the semiconductor layer and structural integrity for the resulting iCell (either a flexible solar cell using a flexible backplane sheet or a rigid solar cell using a rigid backplane sheet or a semi-flexible solar cell using a semi-flexible backplane sheet). Again, while we may use the term backplane to the combination of the continuous backplane support sheet and patterned metallization structure, more commonly we use the term backplane to refer to the backplane support sheet (for instance, an electrically insulating thin sheet of prepreg) which is attached to the semiconductor substrate backside and supports both the icell semiconductor substrate regions and the overall patterned solar cell metallization structure.

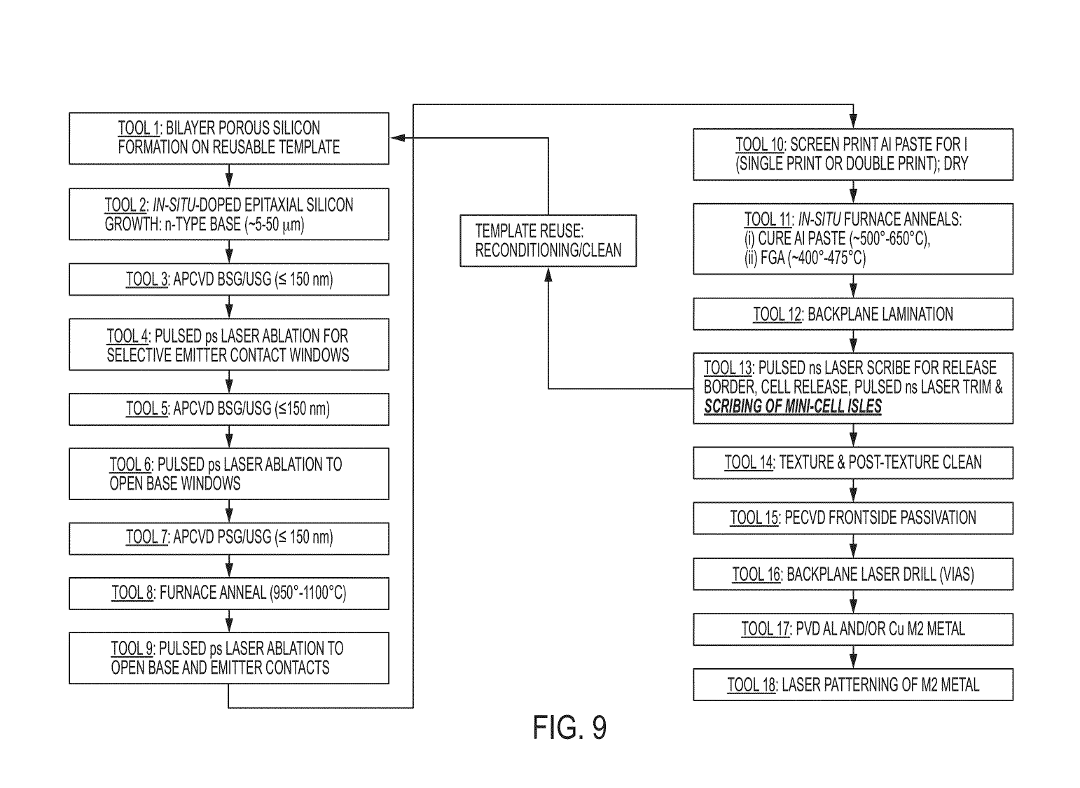

FIG. 9 is a representative backplane-attached iCell manufacturing process flow based on epitaxial silicon and porous silicon lift-off processing. This process flow is for fabrication of backplane-attached, back-contact/back junction solar cells (iCells) using two patterned layers of solar cell metallization (M1 and M2). This example is shown for a solar cell with selective emitter, i.e., a main patterned field emitter with lighter emitter doping formed using a lighter boron-doped silicate glass (first BSG layer with smaller boron doping deposited by Tool 3), and more heavily-boron-doped emitter contact regions using a more heavily boron-doped silicate glass (second BSG layer with larger boron doping deposited by Tool 5). While this example is shown for an IBC solar cell using a double-BSG selective emitter process, the iCell designs are applicable to a wide range of other solar cell structures and process flows, including but not limited to the IBC solar cells without selective emitter (i.e., same emitter boron doping in the field emitter and emitter contact regions). This example is shown for an IBC iCell with an n-type base and p-type emitter. However, the polarities can be changed so that the solar cell has p-type base and n-type emitter instead.

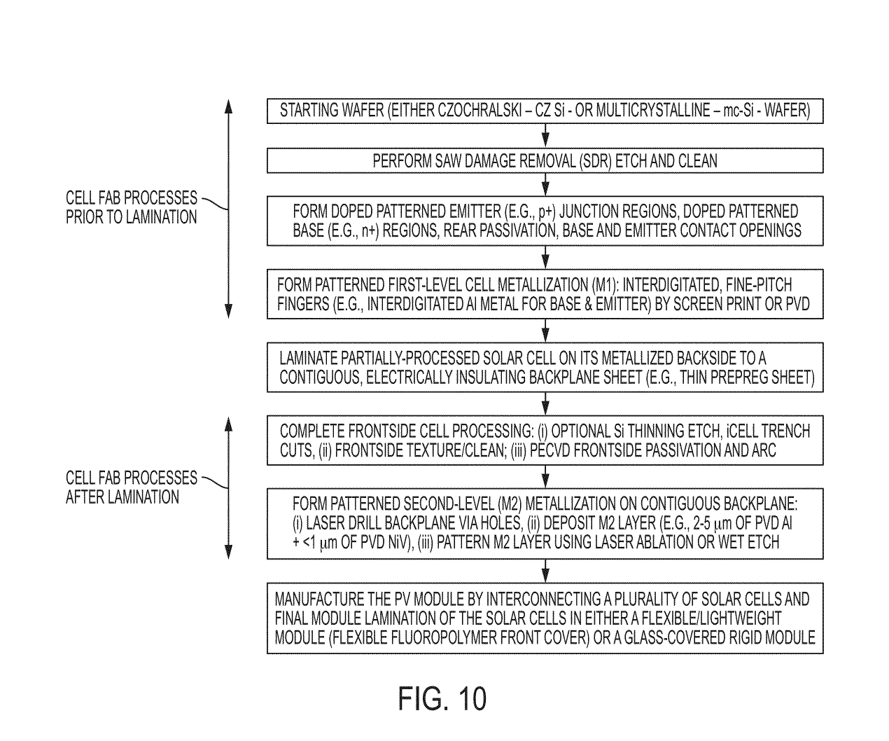

FIG. 10 is a high level solar cell and module fabrication process flow embodiment using starting crystalline (mono-crystalline or multi-crystalline) silicon wafers. FIG. 10 shows a high-level iCell process flow for fabrication of backplane-attached back-contact/back-junction (IBC) iCells using two layers of metallization: M1 and M2. The first layer or level of patterned cell metallization M1 is formed as essentially the last process step among a plurality of front-end cell fab processes prior to the backplane lamination to the partially processed iCell (or a larger continuous backplane attached to a plurality of partially processed iCells when fabricating monolithic modules as described earlier). The front-end cell fab processes outlined in the top 4 boxes of FIG. 10 essentially complete the back-contact/back-junction solar cell backside structure through the patterned M1 layer. Patterned M1 is designed to conform to the iCell isles (sub-cells or mini-cells) and comprises a fine-pitch interdigitated metallization pattern as described for the epitaxial silicon iCell process flow outlined in FIG. 9. In FIG. 10, the fifth box from the top involves attachment or lamination of the backplane layer or sheet to the partially processed icell backside (or to the backsides of a plurality of partially processed iCells when making a monolithic module)—this process step is essentially equivalent to the one performed by Tool 12 in FIG. 9 in case of epitaxial silicon lift-off process). In FIG. 10, the sixth and seventh boxes from the top outline the back-end or post-backplane-attachment (also called post-lamination) cell fab processes to complete the remaining frontside (optional silicon wafer thinning etch to form thinner silicon absorber layer if desired, partitioning trenches, texturization, post-texturization cleaning, passivation and ARC) as well as the via holes and second level or layer of patterned metallization M2. The “post-lamination” processes (or the back-end cell fab processes performed after the backplane attachment) outlined in the sixth and seventh boxes of FIG. 10 essentially correspond to the processes performed by Tools 13 through 18 for the epitaxial silicon lift off process flow shown in FIG. 9. The bottom box in FIG. 10 describes the final assembly of the resulting iCells into either flexible, lightweight PV modules or into rigid glass-covered PV modules. If the process flow results in a monolithic module comprising a plurality of iCells monolithically interconnected together by the patterned M2 (as described earlier for the epitaxial silicon lift off process flow), the remaining PV module fabrication process outlined in the bottom box of FIG. 10 would be simplified since the plurality of the interconnected iCells sharing a larger continuous backplane and the patterned M2 metallization for cell-to-cell interconnections are already electrically interconnected and there is no need for tabbing and/or stringing and/or soldering of the solar cells to one another. The resulting monolithic module can be laminated into either a flexible, lightweight PV module (for instance, using a thin flexible fluoropolymer cover sheet such as ETFE or PFE on the frontside instead of rigid/heavy glass cover sheet) or a rigid, glass-covered PV module.

The design of isles or mini-cells (sub-cells) of an iCell may include various geometrical shapes such as squares, triangles, rectangles, trapezoids, polygons, honeycomb hexagonal isles, or many other possible shapes and sizes. The shapes and sizes of isles, as well as the number of isles in an iCell may be selected to provide optimal attributes for one or a combination of the following considerations: (i) overall crack elimination or mitigation in the master cell (iCell); (ii) enhanced pliability and flexibility/bendability of master cell (iCell) without crack generation and/or propagation and without loss of solar cell or module performance (power conversion efficiency); (iii) reduced metallization thickness and conductivity requirements (and hence, reduced metallization material consumption and processing cost) by reducing the master cell (iCell) current and increasing the iCell voltage (through series connection or a hybrid parallel-series connection of the isles in the monolithic iCell, resulting in scaling up the voltage and scaling down the current); and (iv) providing relatively optimum combination of electrical voltage and current ranges in the resulting icell to facilitate and enable implementation of inexpensive distributed embedded electronics components on the iCells and/or within the laminated PV modules comprising iCells, including but not limited to at least a bypass switch (e.g., rectifying pn junction diode or Schottkty barrier diode) per shade management block comprising at least one iCell, maximum-power-point tracking (MPPT) power optimizers (at least a plurality of MPPT power optimizers embedded in each module, with each MPPT power optimizer dedicated to shade management block comprising at least one of a plurality of series-connected and/or parallel-connected iCells), PV module power switching (with remote control on the power line in the installed PV array in order to switch the PV modules on or off as desired), module status (e.g., power delivery and temperature) during operation of the PV module in the field, etc. For example and as described earlier, in some applications and instances when considered along with other requirements, it may be desired to have smaller (for example triangular shaped) isles near the periphery of the master cell (icell) to reduce crack propagation and/or to improve flexibility/bendability of the resulting iCells and flexible, lightweight PV modules.

Partitioning the main/master cell into an array of isles or sub-cells (such as an array of N×N square or pseudo-square shaped or K triangular-shaped or a combination thereof) and interconnecting those isles in electrical series or a hybrid combination of electrical parallel and electrical series reduces the overall master cell current for each isle or mini-cell—for example by a factor of N×N=N² if all the square-shaped isles are connected in electrical series, or by a factor of K if all the triangular-shaped isles are connected in series. And while the main/master cell or iCell has a maximum-power (mp) current of Iₘₚ, and a maximum-power voltage of Vₘₚ, each series-connected isle (or sub-groups of isles connected in parallel and then in series) will have a maximum-power current of Iₘₚ/N² (assuming N² isles connected in series) and a maximum-power voltage of Vₘₚ (no change in voltage for the isle). Designing the first and second metallization layer patterns, M1 and M2 respectively, such that the isles on a shared continuous or continuous backplane are connected in electrical series results in a main/master cell or icell with a maximum-power current of Iₘₚ/N² and a maximum power voltage of N²×Vₘₚ or a cell (icell) maximum power of Pₘₚ=Iₘₚ×Vₘₚ (the same maximum power as a master cell without mini-cell partitioning).

Thus, a monolithically isled master cell or iCell architecture reduces ohmic losses due to reduced solar cell current and allows for thinner solar cell metallization structure generally and a much thinner M2 layer if applicable or desired. Further, reduced current and increased voltage of the master cell or iCell allows for relatively inexpensive, high-efficiency, maximum-power-point-tracking (MPPT) power optimizer electronics to be directly embedded into the PV module and/or integrated on the solar cell backplane.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

What is claimed is:

1. A photovoltaic solar cell structure, comprising:
a plurality of back-contact solar cells, each of said solar cells having at least:
a light receiving frontside and a passivated backside opposite said light receiving frontside;
a first metal layer on said passivated backside, said first metal layer having base and emitter metallization contact base and emitter regions of said back-contact solar cell;
an electrically insulating backplane layer attached to said backsides of each of said plurality of back-contact solar cells, said electrically insulating backplane covering said first metal layer of each of said back-contact solar cells;
via holes through said continuous backplane layer to portions of said base and emitter metallization of said first metal layer;
a second metal layer on said electrically insulating backplane and contacting said first metal layer through said via holes, said second metal layer electrically connecting at least two of said plurality of back-contact solar cells forming a shade management block comprising at least a fraction of one of said plurality of back-contact solar cells, said shade management block having at least two opposite polarity terminals; and
a bypass switch electrically connected to said opposite polarity terminals.

2. The photovoltaic solar cell structure of claim 1, wherein said bypass switch is a Super Barrier Rectifier.

3. The photovoltaic solar cell structure of claim 1, wherein said bypass switch is a Schottky Barrier Rectifier.

3. The photovoltaic solar cell structure of claim 1, further comprising a copper bussing ribbon.

4. The photovoltaic solar cell structure of claim 1, further comprising an aluminum bussing ribbon.

5. The photovoltaic solar cell structure of claim 1, wherein said plurality of back-contact solar cells are monolithic isled solar cells having semiconductor isles defined by a trench isolation pattern through a semiconductor layer.

6. The photovoltaic solar cell structure of claim 5, wherein each of said monolithic isled solar cells have at least two semiconductor isles connected in electrical series.

7. The photovoltaic solar cell structure of claim 5, wherein each of said monolithic isled solar cells have greater than two semiconductor isles connected in electrical series.

8. The photovoltaic solar cell structure of claim 1, further comprising an MPPT power optimizer electrically connected to said opposite polarity terminals.

9. A photovoltaic solar cell structure, comprising:
a plurality of back-contact monolithic isled solar cells having semiconductor isles defined by a trench isolation pattern through a semiconductor layer, each of said back-contact monolithic isled solar cells having at least:
a light receiving frontside and a passivated backside opposite said light receiving frontside;
a first metal layer on said passivated backside, said first metal layer having base and emitter metallization contact base and emitter regions of said back-contact monolithic isled solar cells;
an electrically insulating backplane layer attached to said backsides of each of said plurality of back-contact solar cells, said electrically insulating backplane covering said first metal layer of each of said back-contact solar cells;
via holes through said continuous backplane layer to portions of said base and emitter metallization of said first metal layer;
a second metal layer on said electrically insulating backplane and contacting said first metal layer through said via holes, said second metal layer electrically connecting at least two of said back-contact monolithic isled solar cells forming a shade management block, said shade management block having at least a two opposite polarity terminals; and
a Schottky Barrier Rectifier electrically connected to said opposite polarity terminals.

10. The photovoltaic solar cell structure of claim 9, further comprising a copper bussing ribbon having a width less than 5 mm and a thickness less than 0.6 mm.

11. The photovoltaic solar cell structure of claim 9, further comprising an aluminum bussing ribbon having a width less than 2 mm and a thickness less than 0.3 mm.

12. The photovoltaic solar cell structure of claim 9 wherein each of said monolithic isled solar cells have at least two semiconductor isles connected in electrical series.

13. The photovoltaic solar cell structure of claim 9, wherein each of said monolithic isled solar cells have greater than two semiconductor isles connected in electrical series.

14. The photovoltaic solar cell structure of claim 9, further comprising an MPPT power optimizer electrically connected to said opposite polarity terminals.
